(19) United States
(12) Patent Application Publication
(10) Pub. No.: US 2026/0313860 A1
(43) Pub. Date: Oct. 8, 2026

(54) APPARATUS, SYSTEM, AND METHODS FOR MODULAR LIQUID-COOLED COMPONENT RACK WITH HOT-SWAP CAPABILITY

(71) Applicant: Iceotope Group Limited, South Yorkshire (GB)

(72) Inventors: Neil Edmunds, Ylöjärvi (FI); Nathan Longhurst, Chesterfield (GB); Joshua Robinson, Sheffield (GB)

(73) Assignee: Iceotope Group Limited, South Yorkshire (GB)

(21) Appl. No.: 19/641,198

(22) Filed: Apr. 7, 2026

Related U.S. Application Data
(60) Provisional application No. 63/793,408, filed on Apr. 23, 2025.
(60) Provisional application No. 63/784,841, filed on Apr. 7, 2025.

(51) Int. Cl. H05K 7/20; H05K 7/14

(52) U.S. Cl. CPC H05K 7/20927; H05K 7/1492; H05K 7/20263; H05K 7/20272; H05K 7/20781

(57) ABSTRACT

A modular liquid-cooled power distribution system includes a component rack, one or more component modules mounted within the component rack, and an external liquid cooling system integrated with the component rack and configured to supply external coolant to the one or more component modules. Each component module comprises a housing defining an internal volume containing dielectric coolant, one or more electrical components at least partially submerged in the dielectric coolant, and a heat exchanger configured to transfer heat from the dielectric coolant to the external coolant.

### CROSS-REFERENCE TO RELATED APPLICATIONS

This application claims the benefit of U.S. Provisional Application No. 63/784,841, titled “APPARATUS, SYSTEM, AND METHODS FOR MODULAR LIQUID-COOLED COMPONENT RACK WITH HOT-SWAP CAPABILITY,” filed on Apr. 7, 2025, and U.S. Provisional Application No. 63/793,408, titled “APPARATUS, SYSTEM, AND METHODS FOR MODULAR LIQUID-COOLED COMPONENT RACK WITH HOT-SWAP CAPABILITY,” filed on Apr. 23, 2025, the entire contents of which are incorporated herein by reference.

### FIELD OF THE PRESENT DISCLOSURE

The present disclosure relates to liquid cooling systems for electronic assemblies, and more particularly to a modular liquid-cooled component rack with hot-swap capability for component modules.

### BACKGROUND

Modern electronic systems face increasingly stringent requirements for thermal management as they integrate more powerful components into confined spaces. In various computing, telecommunications, and industrial applications, there is a continuous drive to improve cooling efficiency and ensure reliable operation under high-density conditions. As electronic devices, such as power supplies become more compact, the need for effective cooling solutions that efficiently dissipate heat while maintaining system integrity becomes increasingly significant. Existing methods have evolved from traditional air cooling to more advanced cooling systems that utilize liquid-based approaches. This evolution underscores the importance of managing heat in environments where continuous and uninterrupted performance is essential.

In many applications, it is desirable to achieve highly efficient cooling while also ensuring that electronic components remain serviceable and maintainable without interrupting overall system operation. Efforts have been made to develop systems that not only remove heat effectively but also facilitate continuous operation during routine servicing, reducing downtime, and enhancing overall system resilience. As such, there is a demand for systems that support hot-swap functionality that balance high thermal efficiency with the ease of component replacement.

A general challenge exists in reconciling high-performance cooling methods with the operational flexibility required in modern electronic assemblies. Many existing solutions necessitate temporary cessation of cooling operations to service or replace functional units, potentially introducing thermal stress and compromising reliability. Moreover, the integration of cooling circuits with electronic modules often involves complex connectivity and dependency issues, which can limit overall system uptime. Addressing these challenges requires a careful balance of cooling efficiency and ease of maintenance to achieve uninterrupted thermal management in systems that require individual components to be serviced or replaced quickly.

As such, there exists a desire for a system that enables a user to hot swap liquid cooled components while not interfering with the cooling of other component modules in the system.

### SUMMARY

This Summary is provided to introduce a selection of concepts in a simplified form that are further described below in the Detailed Description. This Summary is not intended to identify key features or essential features, nor is it intended to limit the scope of the claims included herewith.

According to an aspect of the present disclosure, a modular liquid-cooled power distribution system is provided. The system may include a component rack, one or more component modules mounted within the component rack, and an external liquid cooling system integrated with the component rack and configured to supply external coolant to the one or more component modules. Each component module may comprise a housing defining an internal volume containing dielectric coolant, one or more electrical components at least partially submerged in the dielectric coolant, and a heat exchanger configured to transfer heat from the dielectric coolant to the external coolant.

In some embodiments, the modular liquid-cooled power distribution system may include one or more of the following features. Each of the one or more component modules may comprise a first compartment and a second compartment, wherein the second compartment contains the one or more electrical components, and the heat exchanger is disposed within the first compartment. The first compartment may be configured to act as a sump having a lower coolant level than the second compartment, and the dielectric coolant may overflow from the second compartment into the first compartment via one or more apertures. Each component module may further comprise a manifold positioned along a length of the second compartment, the manifold including a plurality of apertures configured to disperse cooled dielectric coolant across the one or more electrical components. Each component module may further comprise a third compartment, wherein the external coolant from the external liquid cooling system interfaces with the heat exchanger in the third compartment to remove heat from the heat exchanger. Each component module may comprise blind mate fittings configured to facilitate hot-swapping of the component modules without disrupting operation of the external liquid cooling system. Each of the one or more component modules may further comprise a pump to circulate the dielectric coolant within the housing. Each of the one or more component modules may further comprise a coolant hose disposed between the pump and the heat exchanger, the coolant hose configured to transfer the dielectric coolant from the pump to the heat exchanger. The component rack may include a power input configured to receive three-phase AC input and coolant inputs configured to supply the external coolant to each of the one or more component modules.

Aspects of the present disclosure may further relate to, a component module for a liquid-cooled power distribution system is provided. The component module may include a housing defining an internal volume, dielectric coolant contained within the internal volume, one or more electrical components disposed within the internal volume and at least partially submerged in the dielectric coolant, a pump configured to circulate the dielectric coolant within the internal volume, and a heat exchange assembly configured to transfer heat from the dielectric coolant to an external coolant supplied by an external liquid cooling system.

In some embodiments, the component module may include one or more of the following features. The housing may be configured to maintain a form factor compatible with air-cooled component modules. The component module may further comprise a coolant hose disposed between the pump and the heat exchange assembly, the coolant hose configured to transfer the dielectric coolant from the pump to the heat exchange assembly, wherein the coolant hose is formed from a resilient material configured to fit between the one or more electrical components within the housing. The heat exchange assembly may comprise a plurality of heat fins configured to receive heat from the dielectric coolant. The plurality of heat fins may comprise electrical component-side heat fins configured to interface with the dielectric coolant and power connection-side heat fins configured to interface with the external coolant. The housing may include a first compartment, a second compartment, and a third compartment, wherein the pump is disposed within the first compartment. The component module may further comprise blind mate fittings configured to connect the component module to power and coolant systems of a component rack upon insertion of the component module into the component rack.

The foregoing general description of the illustrative embodiments and the following detailed description thereof are merely exemplary aspects of the teachings of this disclosure and are not restrictive.

### BRIEF DESCRIPTION OF FIGURES

The incorporated drawings, which are incorporated in and constitute a part of this specification exemplify the aspects of the present disclosure and, together with the description, explain and illustrate principles of this disclosure.

FIG. 1 illustrates an embodiment of a modular component rack, according to aspects of the present disclosure.

FIG. 2 illustrates an embodiment of the modular component rack, according to aspects of the present disclosure.

FIG. 3 illustrates an embodiment of a component rack casing, according to aspects of the present disclosure.

FIG. 4 illustrates a front view of a wide form factor rack, according to aspects of the present disclosure.

FIG. 5 illustrates an embodiment of a modular component rack with vertical powershelves, according to aspects of the present disclosure.

FIG. 6 illustrates an embodiment of the modular component rack with vertical powershelves, according to aspects of the present disclosure.

FIG. 7 illustrates an embodiment of the modular component rack with vertical powershelves, according to aspects of the present disclosure.

FIG. 8 illustrates an embodiment of a modular component rack, according to aspects of the present disclosure.

FIG. 9A illustrates an embodiment of a component module in a partially inserted position, according to aspects of the present disclosure.

FIG. 9B illustrates an embodiment of the component module of FIG. 9A in a fully inserted position, according to aspects of the present disclosure.

FIG. 10 illustrates an embodiment of a component module, according to aspects of the present disclosure.

FIG. 11 illustrates an embodiment of the component module, according to aspects of the present disclosure.

FIG. 12 illustrates an embodiment of the component module, according to aspects of the present disclosure.

FIG. 13 illustrates an embodiment of the component module, according to aspects of the present disclosure.

FIG. 14 illustrates an embodiment of the component module, according to aspects of the present disclosure.

FIG. 15 illustrates an embodiment of the component module, according to aspects of the present disclosure.

FIG. 16A illustrates an embodiment of a traditional component module without a covering, according to aspects of the present disclosure.

FIG. 16B illustrates an embodiment of the traditional component module with a covering, according to aspects of the present disclosure.

FIG. 17 illustrates an embodiment of a component module, according to aspects of the present disclosure.

FIG. 18 illustrates an embodiment of the component module of FIG. 17 showing a dielectric coolant flow path, according to aspects of the present disclosure.

FIG. 19 illustrates an embodiment of a component module, according to aspects of the present disclosure.

FIG. 20 illustrates an embodiment of the component module of FIG. 19 showing a dielectric coolant flow path, according to aspects of the present disclosure.

### DETAILED DESCRIPTION

In the following detailed description, reference will be made to the accompanying drawing(s), in which identical functional elements are designated with like numerals. The aforementioned accompanying drawings show by way of illustration, and not by way of limitation, specific aspects, and implementations consistent with principles of this disclosure. These implementations are described in sufficient detail to enable those skilled in the art to practice the disclosure and it is to be understood that other implementations may be utilized and that structural changes and/or substitutions of various elements may be made without departing from the scope and spirit of this disclosure. The following detailed description is, therefore, not to be construed in a limited sense.

It is noted that description herein is not intended as an extensive overview, and as such, concepts may be simplified in the interests of clarity and brevity.

All documents mentioned in this application are hereby incorporated by reference in their entirety. Any process described in this application may be performed in any order and may omit any of the steps in the process. Processes may also be combined with other processes or steps of other processes.

Referring generally to the figures, aspects of the present disclosure may relate to a modular liquid-cooled power distribution system. The modular liquid-cooled power distribution system may include a component rack configured to house one or more component modules. Each component module may be configured to provide power output, such as converting alternating current (AC) power to direct current (DC) power for distribution to computing or other electronic systems.

Each of the one or more component modules may include a housing defining an internal volume. In an embodiment, the internal volume may contain a coolant. In one or more embodiments, the coolant may comprise a dielectric fluid configured for single-phase or two-phase cooling, including, but not limited to, hydrocarbon-based fluids and other suitable cooling fluids.

In an embodiment, one or more electrical components may be disposed within the internal volume. Said electrical components may be thermally coupled to the coolant. In one or more embodiments, the one or more electrical components may be at least partially submerged in the coolant, such that the coolant may absorb heat from said components, providing thermal management for the component module.

Each component module may further include a heat exchanger configured to transfer heat from the coolant to an external cooling system. For instance, the modular liquid-cooled power distribution system may feature an external liquid cooling system that supplies external coolant, such as facility water, to each of the one or more component modules. In an embodiment, the external liquid cooling system may be integrated within the component rack.

In one or more embodiments, the heat exchanger may facilitate heat transfer between the coolant within each of the one or more component modules and the external coolant.

In one or more embodiments, the component rack may include one or more component modules, each configured to contain a different coolant. For example, a first component module may contain a first coolant, while a second component module may contain a second coolant. The use of such different coolants within the respective component modules may facilitate targeted cooling of different electrical components housed therein.

In some aspects, each of the one or more component modules may include a pump. In an embodiment, the pump may circulate the coolant within the internal volume of the housing. The pump may also drive heated dielectric coolant to the heat exchanger and/or drive cooled dielectric coolant to the one or more component modules.

The modular liquid-cooled power distribution system may support hot-swap capability for the one or more component modules. Each of the one or more component modules may include blind mate fittings configured to facilitate insertion and removal of said component modules from the component rack without disrupting operation of other component modules or the external liquid cooling system. The blind mate fittings may automatically engage power and/or coolant connections when the component modules are inserted into the component rack and may automatically disconnect when removed.

In some implementations, the component rack may include a plurality of component modules arranged in an N+1 redundancy configuration. In such a configuration, one component module may serve as a backup, allowing the modular liquid-cooled power distribution system to maintain power output even if one component module fails or requires maintenance. The hot-swap capability may enable an operator to remove and replace individual component modules without interrupting operation of the remaining component modules in the component rack.

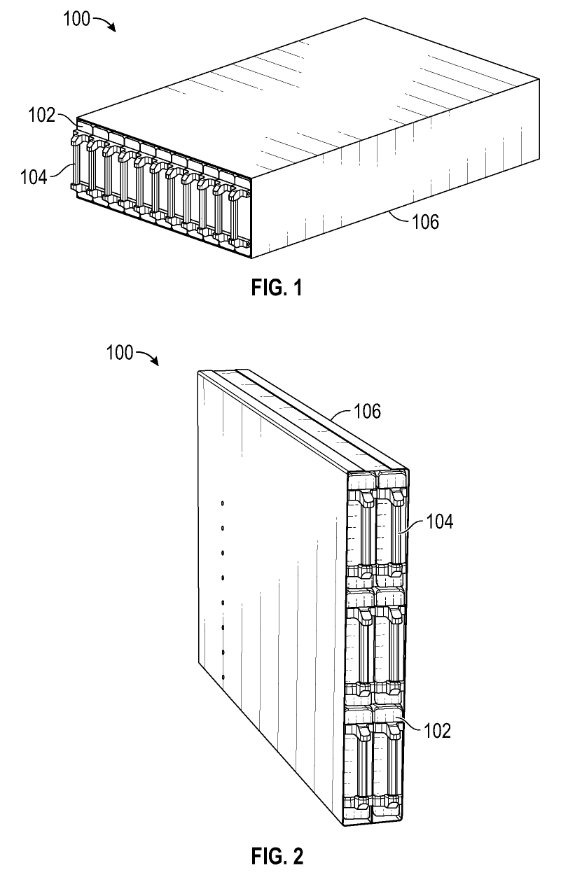

Referring to FIGS. 1 and 2, aspects of the present disclosure relate to a modular component rack 100. The modular component rack 100 is designed to offer flexibility in configuration, allowing arrangement in either a horizontal (as depicted in FIG. 1) or vertical (as depicted in FIG. 2) stack setups. Such flexibility is important for accommodating various spatial constraints and operational requirements in different environments.

In an embodiment, the component rack 100 may house one or more component modules 102. The component rack 100 may facilitate easy access to the one or more component modules 102, allowing for hot-swapping capabilities as discussed in further detail below.

In one or more embodiments, each of the one or more component modules 102 may include a module removal handle (the “handle”) 104. Such a handle 104 may be positioned at, and/or interface with, a front face of each of the one or more component modules 102, to facilitate removal and insertion of the component modules 102 within the rack 100.

In an embodiment, the modular component rack 100 may include a casing 106 that houses the one or more component modules 102. For example, the casing 106 may provide structural support and define the overall form factor of the modular component rack 100. In one or more embodiments, a user may grasp the module removal handle 104 to slide the component module 102 out of, or into, the casing 106.

Furthermore, the one or more component modules 102 may be arranged in a horizontal configuration within the casing 106. In the horizontal configuration, said modules 102 may be positioned in a side-by-side arrangement, with each component module 102 being individually accessible from the front of the modular component rack 100. The horizontal configuration may allow each of the one or more component modules 102 to occupy its own slot within the modular component rack 100. The vertical arrangement of the one or more component modules 102 within the casing 106 may allow for efficient use of vertical space.

In some implementations, the rack 100 may be positioned on either side of a server or other computer rack to supply power to the system. Each rack 100 may be equipped with a power input, such as an AC input, which may allow for independent operation and redundancy.

Moreover, the arrangement of the one or more component modules 102 within the casing 106 may allow for scalable power distribution and redundancy configurations. In some implementations, the modular component rack 100 may include a plurality of component modules 102 arranged in an N+1 redundancy configuration, where one component module 102 serves as a backup. The N+1 redundancy configuration may allow the modular component rack 100 to maintain power output even if one component module 102 fails or requires maintenance.

The design of the modular component rack 100 may provide access to the one or more component modules 102 while maintaining a compact form factor suitable for integration into data center and/or computing environments. Each of the one or more component modules 102 may be hot-swappable, allowing for removal and replacement of individual component modules 102 without disrupting operation of other component modules 102 within the modular component rack 100. The hot-swap capability may enable maintenance and replacement operations to be performed while the modular component rack 100 continues to operate.

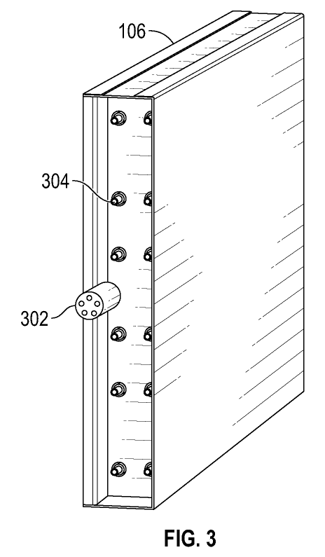

Turning to FIG. 3, a rear portion of the casing 106 is illustrated. In an embodiment, the casing 106 may include at least one of a power input/output 302 and a coolant input/output 304 positioned on the rear surface of the casing 106.

In one or more embodiments, the power input/output 302 may supply power to the one or more component modules 102 housed within the casing 106. The power input/output 302 may accommodate various electrical standards and requirements, providing compatibility with different environments and applications. In some aspects, the power input/output 302 may include configurations for three-phase AC input. The three-phase AC input may range from 400 to 480 volts, which may be suitable for standard industrial power applications. In some cases, other voltage inputs may be used depending on the requirements of the installation environment.

Further, the coolant input/output 304 may be arranged as a series of connection points extending vertically along the rear surface of the casing 106. In an embodiment, the coolant input/output 304 may supply coolant to each of the one or more component modules 102 to maintain thermal conditions within each component module 102.

In some aspects, the coolant used may be water, which may serve as a medium for transferring heat away from coolant contained within each of the one or more component modules 102. The heat transfer between the external coolant, supplied through the coolant input/output 304, and the coolant within each of the one or more component modules 102 may be facilitated through a heat exchanger. For instance, such a heat exchanger may be disposed within each of the one or more component modules 102.

The arrangement of the coolant input/output 304 as multiple connection points may allow for individual coolant supply to each of the one or more component modules 102. The individual coolant supply may facilitate independent cooling circuits that support hot-swap functionality, enabling removal and replacement of individual component modules 102 without disrupting coolant flow to other component modules 102 within the casing 106.

The positioning of the power input/output 302 and the coolant input/output 304 at the rear of the casing 106 may enable organized cable and fluid line management. In some implementations, the power input/output 302 and the coolant input/output 304 may be located at other suitable locations on the casing 106 depending on the configuration requirements of the installation.

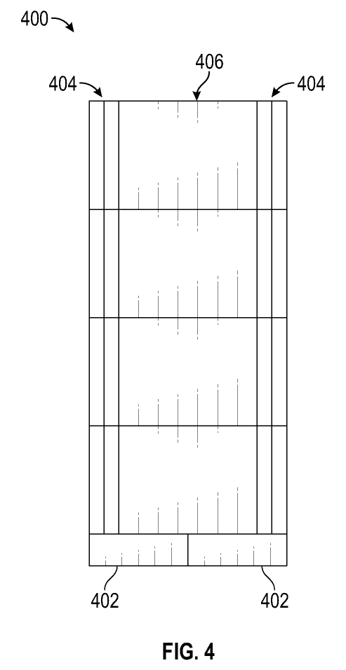

Referring to FIG. 4, a wide form factor rack 400 is shown configured for a modular liquid-cooled power distribution system. In an embodiment, the wide form factor rack 400 may include one or more coolant distribution units (the “CDUs” or “CDU”) 402, AC-DC power supply units (the “PSUs” or “PSU”) 404, and compute trays 406 arranged in a vertical configuration.

The CDUs 402 may be positioned at a bottom portion of the wide form factor rack 400. The CDUs 402 may be configured to provide coolant distribution for thermal management of the wide form factor rack 400. In some aspects, the CDUs 402 may supply facility coolant to the PSUs 404 and the compute trays 406 to remove heat generated during operation. The positioning of the CDUs 402 at the bottom portion of the wide form factor rack 400 may facilitate coolant distribution throughout the rack structure.

Moreover, the PSUs 404 may be arranged vertically along left and right sides of the wide form factor rack 400. For instance, the PSUs 404 may be positioned above the CDUs 402 and extend along the height of the wide form factor rack 400.

In an embodiment, the PSUs 404 may convert alternating current power to direct current power for distribution to the compute trays 406 and other electronic systems within the wide form factor rack 400. In some implementations, each PSU 404 may be configured in an N+1 redundancy configuration, where one PSU 404 serves as a backup to maintain power output in the event of a failure or during maintenance operations.

In one or more embodiments, the compute trays 406 may be positioned in a central portion of the wide form factor rack 400. For example, the compute trays 406 may be arranged in a stacked configuration between the PSUs 404 on either side of the wide form factor rack 400. The compute trays 406 may extend vertically through a central region of the wide form factor rack 400.

In some aspects, the compute trays 406 may house computing components such as processors, memory, and other electronic devices that receive power from the PSUs 404. This configuration may facilitate efficient power delivery from the PSUs 404 to the compute trays 406 by reducing the distance between power sources and computing loads.

Furthermore, positioning the CDUs 402 at the bottom of the wide form factor rack 400 may enable coolant to be distributed to both the PSUs 404 and the compute trays 406, providing thermal management across the wide form factor rack 400. In some implementations, the PSUs 404 may include liquid-cooled component modules such as the one or more component modules 102 described herein.

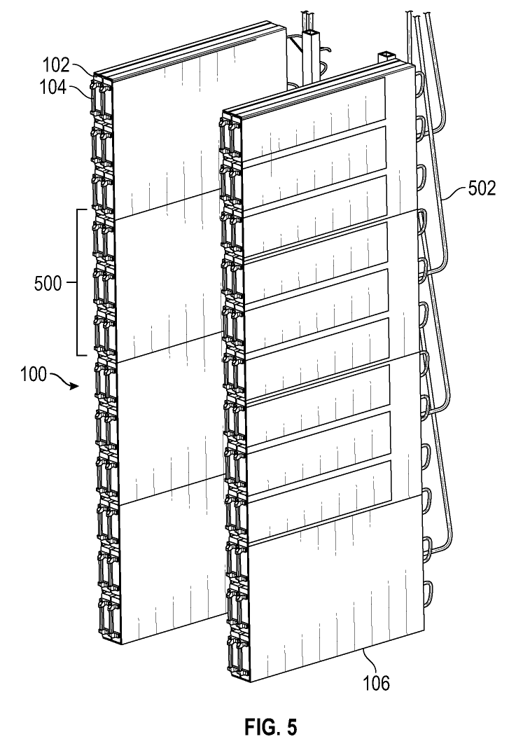

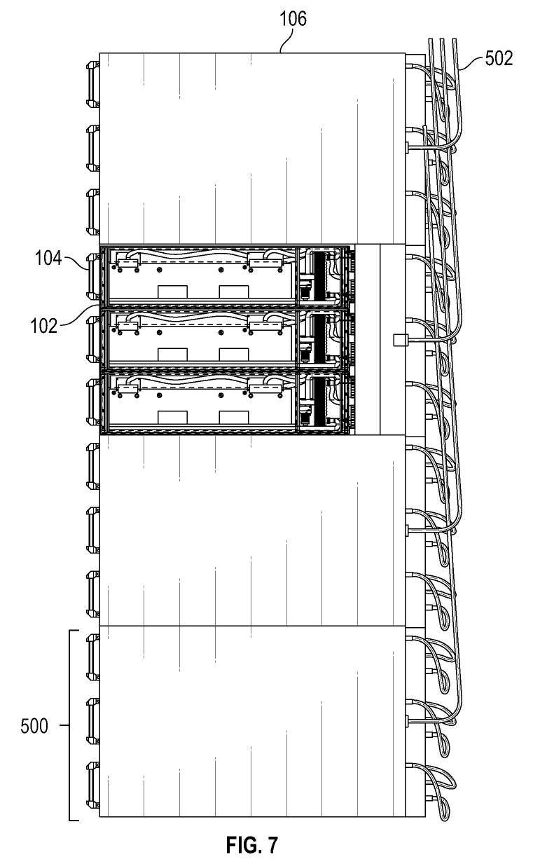

Referring to FIGS. 5-7, the modular component rack 100 may include one or more vertical powershelves 500 arranged within the casing 106. In an embodiment, each of the one or more vertical powershelves 500 may extend along the height of the modular component rack 100.

In an embodiment, each of the one or more vertical powershelves 500 may house the one or more component modules 102. In some implementations, each of the one or more vertical powershelves 500 may include six component modules 102, with each component module 102 configured to provide approximately 10 kW of power output.

In some implementations, the modular component rack 100 may include eight vertical powershelves 500 arranged in a 2OU configuration. With each vertical powershelf 500 providing approximately 50 kW of power output, the eight vertical powershelves 500 may support a total rack power of approximately 400 kW.

The component modules 102 may be arranged in an N+1 redundancy configuration, where five or seven component modules 102 provide active power output and one component module 102 serves as a backup, thus maintaining redundancy for continued operation in the event of a component module 102 failure or during maintenance operations.

In an embodiment, each of the one or more vertical powershelves 500 may have a 2OU form factor. That is, said powershelves 502 may house two component modules 102 arranged side-by-side. In some aspects, the one or more vertical powershelves 500 may have dimensions of approximately 96 mm in width (W), 528 mm in height (H), and 850 mm in depth (D). The height dimension of 528 mm may correspond to a 21-inch Open Compute Project (OCP) fit, providing compatibility with standard rack configurations used in data center environments.

In an embodiment, the one or more vertical powershelves 500 may include an AC power input 502 positioned at an upper portion of the modular component rack 100 to provide electrical power to the vertical powershelf 500 and the one or more component modules 102 housed therein. In some implementations, each of the one or more vertical powershelves 500 may have an independent AC power input 502, allowing for independent operation of each vertical powershelf 500 within the modular component rack 100.

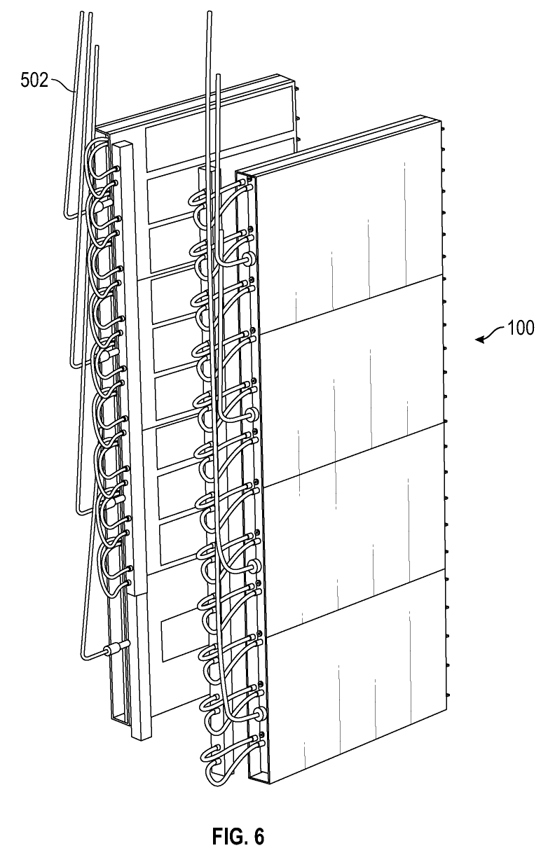

With reference to FIG. 6, the one or more vertical powershelves 500 may include fluid connections that connect each vertical powershelf 500 to a manifold system within the modular component rack 100. In some aspects, each component module 102 within the vertical powershelf 500 may connect directly to a main rack manifold.

In some aspects, each adjacent set of the one or more vertical powershelves 500 may provide DC output to an independent section of a DC busbar. Each independent busbar section may be configured to handle approximately 100 kW of power, allowing for safe and effective current distribution throughout the rack 100. The arrangement of the vertical powershelves 500 with independent busbar sections may provide segmented power distribution, enabling isolation of power delivery to different portions of the rack system.

In some implementations, the component modules 102 may be single-phase power modules. Single-phase component modules 102 may be arranged in groups of three to support three-phase AC input. The grouping of three single-phase component modules 102 may allow each component module 102 in the group to handle one phase of the three-phase AC input. In such configurations, the modular component rack 100 may include multiple groups of three component modules 102, with each group connected to a three-phase AC power source.

In other implementations, the component modules 102 may be three-phase input power supplies. Three-phase input power supplies may be configured to receive three-phase AC input directly, eliminating the requirement to group three single-phase component modules 102 together. The use of three-phase input power supplies may simplify the configuration of the modular component rack 100 and may provide flexibility in the arrangement of the component modules 102 within the modular component rack 100.

In an embodiment, the modular component rack 100 may include a control unit configured to control power distribution and balancing among the component modules 102. The control unit may monitor power output from each component module 102 and may adjust power distribution to balance loads across the component modules 102. In some implementations, the control unit may be positioned within the modular component rack 100 alongside the component modules 102. The control unit may communicate with each component module 102 to coordinate power distribution operations.

Moreover, the external liquid cooling system may include thermal control system (TCS) water loop connectors configured to supply external coolant to each independent component module 102. The TCS water loop connectors may be positioned at the component rack casing 106 and may provide individual coolant supply connections to each component module 102 to facilitate independent cooling circuits for each component module 102, supporting hot-swap functionality by enabling removal and replacement of individual component modules 102 without disrupting coolant flow to other component modules 102 within the modular component rack 100.

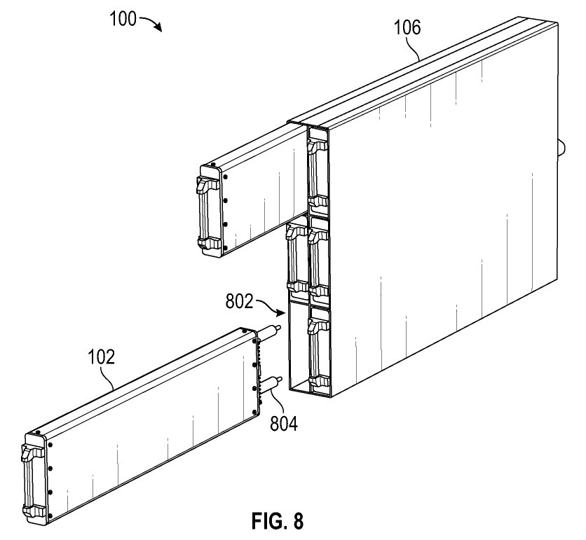

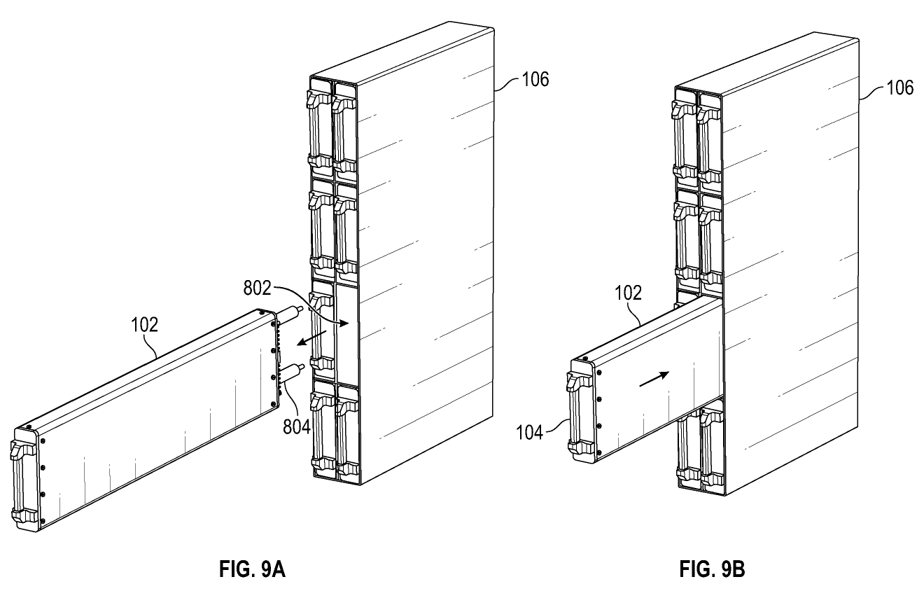

Moving to FIGS. 8-9B, the casing 106 may define a plurality of component module sockets 802. Each component module socket 802 may receive and secure an individual component module 102 within the modular component rack 100.

The component module socket 802 may include blind mate power and fluid connections 804 positioned at an interface between the component module 102 and the component module socket 802. The blind mate power and fluid connections 804 may be configured to automatically engage when the component module 102 is inserted into the component module socket 802 and to automatically disconnect when the component module 102 is removed from the component module socket 802. The blind mate power and fluid connections 804 may allow each component module 102 to connect to power and cooling systems of the modular component rack 100 without manual intervention.

In an embodiment, the arrangement of the blind mate power and fluid connections 804 may facilitate hot-swapping of individual component modules 102 without disrupting operation of other component modules 102 within the modular component rack 100. The blind mate power and fluid connections 804 may include electrical connectors configured to provide power input to the component module 102 and fluid connectors configured to supply external coolant to the component module 102.

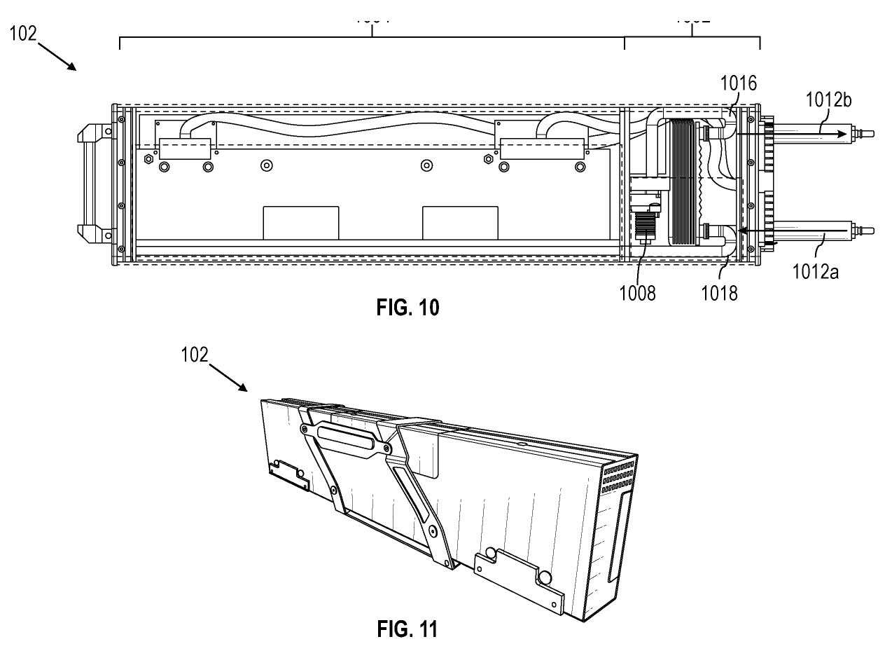

Referring to FIGS. 10-11, an internal volume of the component module 102 may be depicted. In an embodiment, the component module 102 may include one or more compartments. Specifically, the internal volume of the component module may feature a first compartment 1002 and a second compartment 1004.

In one or more embodiments, the first compartment 1002 may house a plate heat exchanger 1006 and a pump 1008. The plate heat exchanger 1006 may serve as an interface between two separate cooling loops. In some aspects, the plate heat exchanger 1006 may facilitate heat transfer between coolant circulating within the component module 102 and the external coolant circulating through the component rack 100.

In some implementations, the plate heat exchanger 1006 may be constructed from stainless steel to provide durability and resistance to corrosion when interfacing with both the coolant and the external coolant.

In an embodiment, the pump 1008 may be disposed within the first compartment 1002 and may circulate the coolant within the component module 102. In some aspects, the pump 1008 may be configured for quiet operation and high reliability to provide continuous cooling of the electrical components within the component module 102. In some aspects, the pump 1008 may be a resilient micro pump able to withstand extended operation while maintaining consistent coolant flow rates. The resilient construction of the pump 1008 may contribute to the overall reliability of the component module 102.

The second compartment 1004 may contain one or more electrical components. In some implementations, the one or more electrical components may be at least partially submerged in the coolant. For example, the coolant may circulate within the second compartment 1004 to absorb heat from the one or more electrical components therein.

The two-compartment design of the component module 102 may offer several advantages. Specifically, the first compartment 1002 may act as a sump having a lower coolant level than the second compartment 1004. In such an embodiment, the first compartment 1002 may regulate the level of coolant in the second compartment 1004 by allowing coolant from the second compartment 1004 to overflow into the first compartment 1002 via one or more apertures. In an embodiment, the apertures may be disposed in the plate heat exchanger 1006.

In one or more embodiments, the component module 102 may include a first coolant loop inlet 1012a and a first cooling loop outlet 1012b associated with the external coolant circuit. The first coolant loop inlet 1012aand the first cooling loop outlet 1012b may be positioned adjacent to the plate heat exchanger 1006 to facilitate heat transfer between the dielectric coolant and the external coolant. The external coolant, such as facility water, may enter the component module 102 into the first compartment 1002 through the first coolant loop inlet 1012a, pass through the plate heat exchanger 1006 to absorb heat from the dielectric coolant in the second compartment 1004, and exit through the first cooling loop outlet 1012b.

In an embodiment, the component modules 102 may include a first conduit 1016 extending from the pump 1008 toward the plate heat exchanger 1006. The first conduit 1016 may transport coolant from the pump 1008 to the plate heat exchanger 1006 for cooling.

In one or more embodiments, the component modules 102 may include a second conduit 1018 positioned to return cooled dielectric coolant from the plate heat exchanger 1006 back into the second compartment 1004 for distribution across the one or more electrical components. The first conduit 1016 and the second conduit 1018 may be routed within the component module 102 to enable continuous circulation of the coolant between the first compartment 1002 and the second compartment 1004.

In an embodiment, the coolant may circulate within the component module 102, absorbing heat from the one or more electrical components in the second compartment 1004. The heated coolant may then overflow into the first compartment 1002, where the pump 1008 may transport the dielectric coolant through the first conduit 1016 to the plate heat exchanger 1006. The plate heat exchanger 1006 may transfer heat from the dielectric coolant to the external coolant. The cooled dielectric coolant may then flow through the second conduit 1018 back into the second compartment 1004 to continue the cooling cycle.

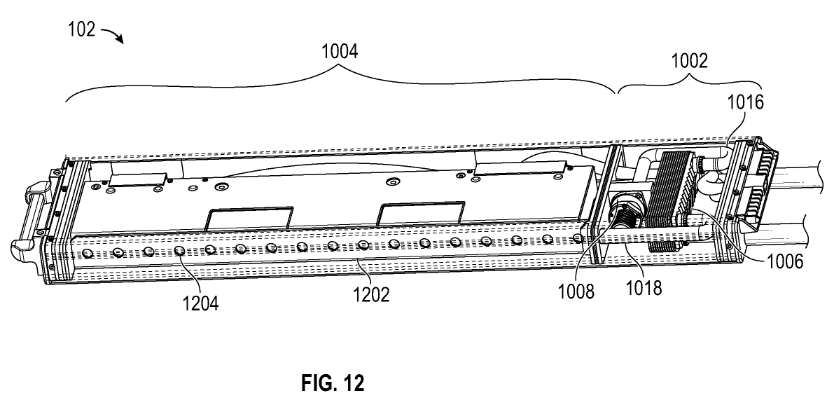

Referring to FIG. 12, the one or more component modules 102 may employ a sophisticated circulation system for its coolant, designed to efficiently manage heat throughout the component module 102. In some implementations, the movement of the coolant through the component module 102 may follow a specific path to optimize cooling performance.

In an embodiment, the pump 1008 may be disposed within the first compartment 1002 and may be configured to transport coolant through a first conduit 1016. The first conduit 1016 may direct the coolant to the plate heat exchanger 1006, where the dielectric coolant may transfer heat to external coolant circulating through the component rack 100.

Furthermore, once cooled by the plate heat exchanger 1006, the coolant may flow through a second conduit 1018. The second conduit 1018 may transport the cooled dielectric coolant into a second compartment manifold 1202 positioned along a length of the second compartment 1004, providing distribution of the cooled coolant to the one or more electrical components housed within the second compartment 1004.

The second compartment manifold 1202 may include a plurality of second compartment manifold apertures 1204. The second compartment manifold apertures 1204 may be configured to disperse the cooled dielectric coolant across the one or more electrical components within the second compartment 1004. In some implementations, the second compartment manifold apertures 1204 may be evenly spaced along the second compartment manifold 1202 to provide uniform coolant distribution across the one or more electrical components.

In some aspects, spacing and sizing of the second compartment manifold apertures 1204 may be customized to achieve specific flow rates and flow patterns. The customization of the second compartment manifold apertures 1204 may allow for targeted cooling, directing a higher volume of cooled dielectric coolant to areas of the second compartment 1004 where components generating higher amounts of heat are located. In such implementations, the second compartment manifold apertures 1204 positioned adjacent to high-heat components may have larger diameters or closer spacing than the second compartment manifold apertures 1204 positioned adjacent to lower-heat components.

In an embodiment, the dispersed coolant may come into direct contact with the one or more electrical components in the second compartment 1004, absorbing heat through immersion cooling. After absorbing heat from the one or more electrical components, the warmed dielectric coolant may overflow from the second compartment 1004 into the first compartment 1002 via one or more apertures, where the cooling cycle may begin again.

In some implementations, the internal volume of the component module 102 may be nearly fully flooded with coolant. Such a module 102 may include an air gap to accommodate thermal expansion of the coolant during operation. The air gap may allow the dielectric coolant to expand as the dielectric coolant absorbs heat from the one or more electrical components without creating excessive pressure within the internal volume of the component module 102.

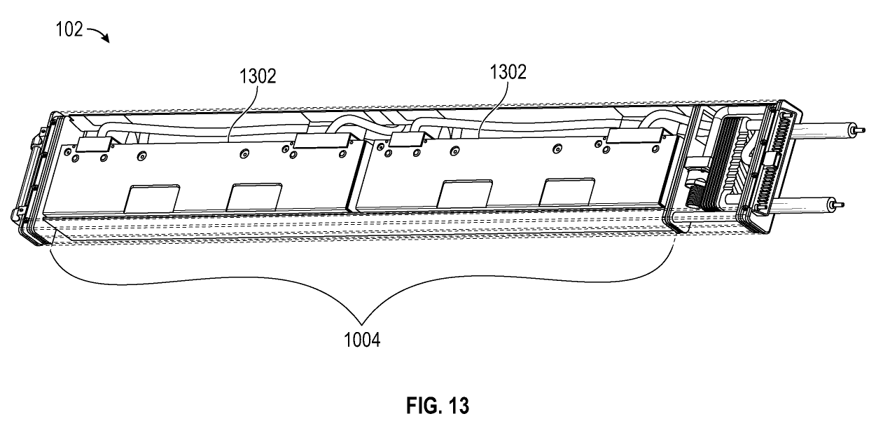

Referring to FIG. 13, the component module 102 may include end-to-end electrical components 1302 arranged within the second compartment 1004. The component module 102 may house two or more power supplies or electrical components in an end-to-end arrangement within the second compartment 1004. The end-to-end electrical components 1302 may be positioned in series along a length of the second compartment 1004, with each end-to-end electrical component 1302 including surface-mounted elements and connection interfaces.

In one or more embodiments, the end-to-end arrangement of the end-to-end electrical components 1302 within the second compartment 1004 may provide increased power density compared to single-component configurations. The second compartment 1004 may be configured to accommodate the multi-component configuration, including shared cooling interfaces, power connections, and structural supports configured for the end-to-end arrangement. In some implementations, the end-to-end electrical components 1302 may be at least partially submerged in dielectric coolant contained within the second compartment 1004, allowing the dielectric coolant to absorb heat from the end-to-end electrical components 1302 through direct contact.

The end-to-end arrangement of the end-to-end electrical components 1302 may allow for flexible power output configurations. In some aspects, two or more power supplies arranged as end-to-end electrical components 1302 may operate independently to provide redundancy within each component module 102 and/or may allow for load balancing across the end-to-end electrical components 1302. In other aspects, the end-to-end electrical components 1302 may operate in tandem to deliver higher combined power output when increased power capacity is required.

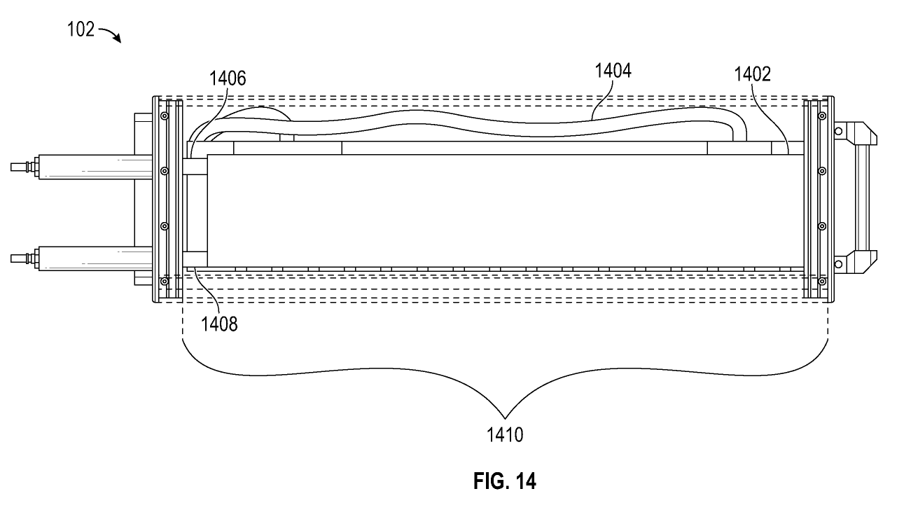

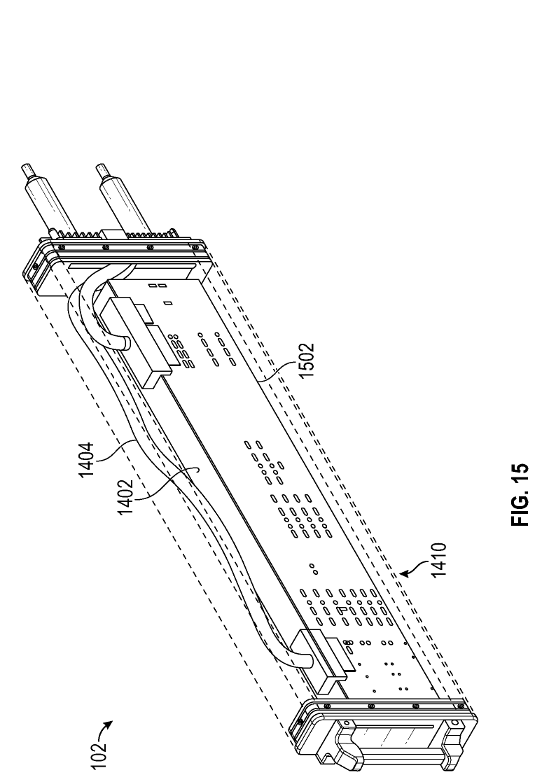

Turning to FIGS. 14-15, an embodiment of the component module 102 including a cold plate may be shown.

The component module 102 may provide an alternative cooling configuration within the modular liquid-cooled power distribution system. In the component module 102, external coolant may flow through a cold plate 1402 to remove heat from electrical components its thermally coupled thereto without requiring dielectric coolant inside the component module 102.

The cold plate 1402 may extend along a length of the component module 102. The cold plate 1402 may be configured to provide thermal management for components positioned within a single component compartment 1410. A power cable 1404 may extend from one end of the component module 102, providing electrical connectivity to external power sources.

In an embodiment, the component module 102 may include a coolant outlet 1406 and a coolant inlet 1408 positioned at opposing sides of the component module 102. The coolant outlet 1406 and the coolant inlet 1408 may enable external coolant, such as facility water, to flow through the cold plate 1402 to remove heat from components in thermal contact with the cold plate 1402. The single component compartment 1410 may be positioned beneath the cold plate 1402, representing an area where one or more electrical components may be positioned in thermal contact with the cold plate 1402.

Referring to FIG. 15, the component module 102 may include a PCB 1502 disposed within the single component compartment 1410. The PCB 1502 may support the electrical components of the component module. A layer of thermal interface material (TIM) may be disposed between the PCB 1502 and the cold plate 1402. The layer of TIM may facilitate thermal transfer from the electrical components to the cold plate 1402. In some aspects, the layer of TIM may include thermal paste or thermal grease configured to provide thermal coupling between heat-generating components on the PCB 1502 and the cold plate 1402.

In some aspects, the cold plate 1402 may include a copper pipe embedded in an aluminum block. The copper pipe may carry the external coolant through the cold plate 1402, while the aluminum block may provide thermal distribution across the surface of the cold plate 1402. In other aspects, the cold plate 1402 may have a narrower profile configuration. The narrower profile may reduce surface area but may increase pressure on the thermal surfaces between the component module and the cold plate 1402.

The component module 102 may provide cooling coverage for a substantial portion of the electrical components within the component module 102. In some cases, the cold plate 1402 may be configured to cool 90-100% of all electrical components in the system. The high cooling coverage may be achievable due to the ability to design the cold plate 1402 to conform and fit to heat-emitting electrical components, such as those on a power supply.

In some implementations, the component module 102 may not include a pump or heat exchanger within its internal volume. Instead, a pumping and cooling circuit may be external to the component module 102. The external pumping and cooling circuit may allow for flow rate control by a facility loop, providing thermal management for the component module 102.

The component module 102 may transfer heat from the electrical components to the external coolant without requiring dielectric coolant inside the component module housing. In such a configuration, the component module 102 may be dust-proof rather than liquid-tight, which may simplify manufacturing of the component module 102ncompared to liquid-tight housing configurations used in immersion cooling systems.

The component module 102 may be configured for easy retrofit with existing cooling loops. In some implementations, the cold plate 1402 may connect to existing facility coolant infrastructure without requiring modification to the external liquid cooling system. The retrofit capability may allow the modular liquid-cooled power distribution system to be integrated into existing data center environments that already include cooling infrastructure. The design of the component module 102 may enable integration with existing rack manifolds, providing compatibility with various installation configurations.

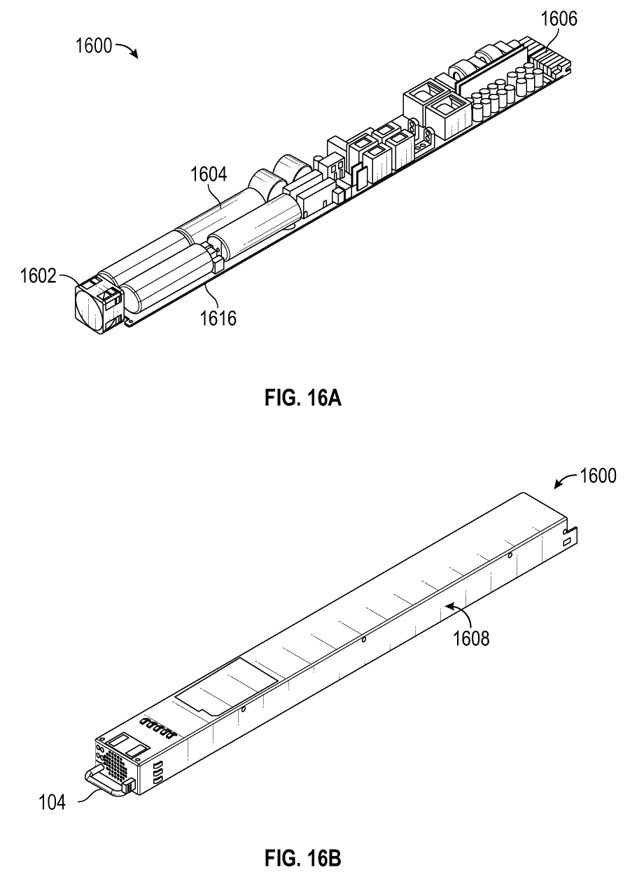

Referring to FIGS. 16A-16B, a traditional component module 1600 is shown for comparison with the liquid-cooled component modules described herein. FIG. 16A illustrates a traditional component module 1600 without a covering 1608, and FIG. 16B illustrates the traditional component module 1600 with the covering 1608.

As shown in FIG. 16A, the traditional component module 1600 includes a fan 1602 positioned at one end of the traditional component module 1600. The fan 1602 may draw air through the traditional component module 1600 to provide cooling for electrical components 1604 disposed within the traditional component module 1600. The electrical components 1604 may include capacitors, transformers, inductors, and other power conversion circuitry arranged along a length of the traditional component module 1600.

Such traditional component modules 1600 may include a PCB base board 1616 extending along the length of the traditional component module 1600. The PCB base board 1616 may serve as a foundation upon which the electrical components 1604 are mounted. The PCB base board 1616 may provide electrical interconnections between the electrical components 1604. A power and communication docking connector 1606 is positioned at an end of the traditional component module 1600 opposite the fan 1602. The power and communication docking connector 1606 may be configured to interface with a backplane or rack system to provide electrical power output and communication signals.

Referring to FIG. 16B, the traditional component module 1600 includes the covering 1608 that encloses the electrical components 1604 of the traditional component module 1600. The covering 1608 may provide protection and structural integrity for the traditional component module 1600. A module removal handle 104 is positioned at one end of the traditional component module 1600 to facilitate extraction and insertion of the traditional component module 1600 from a component rack.

The traditional component module 1600 may have a standard OCP form factor. The standard OCP form factor may allow the traditional component module 1600 to fit within a 1U rack space.

In some implementations, the liquid-cooled component modules described herein may be configured to maintain a form factor compatible with the traditional component module 1600. The liquid-cooled component modules may use a housing material similar to the covering 1608 of the traditional component module 1600, maintaining similar size and electrical properties. In such implementations, a pump may occupy a space similar to that of the fan 1602 in the traditional component module 1600, allowing the liquid-cooled component module to fit within standard dimensions without requiring additional length. A dielectric coolant hose may be routed between the electrical components 1604 within the housing, following a path similar to a power cable route in the traditional component module 1600, to avoid adding height to the housing. The compatibility with the standard OCP form factor may allow the liquid-cooled component modules to be installed in existing rack configurations designed for air-cooled component modules.

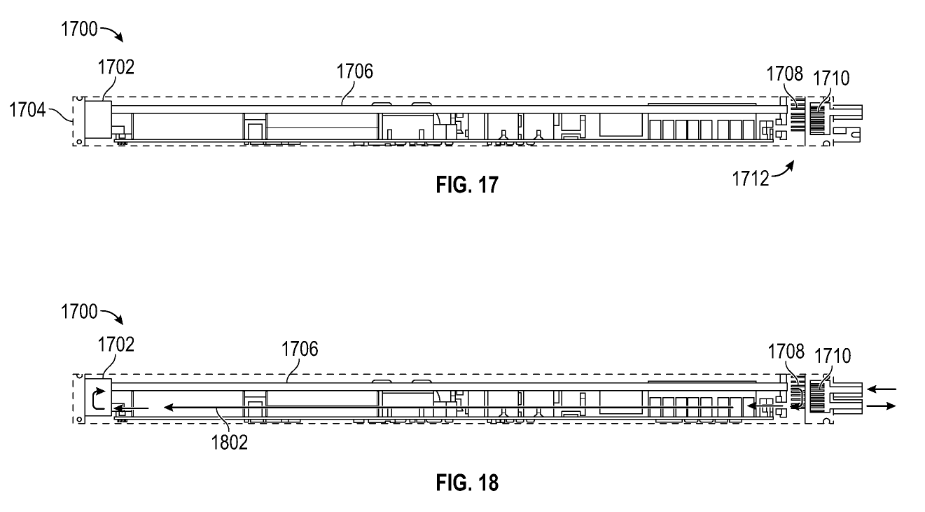

Referring to FIGS. 17-18, a component module 1700 is shown. The component module 1700 may incorporate the disclosure with regard to component module 102 herein. The component module 1700 may provide a liquid-cooled configuration that maintains a form factor compatible with air-cooled component modules. The component module 1700 may include a pump 1702, a liquid tight end cap 1704, a coolant hose 1706, and a heat exchanger assembly 1712.

The pump 1702 may be positioned at one end of the component module 1700. The pump 1702 may occupy a space similar to that of a fan in the traditional air-cooled component module 1600. By positioning the pump 1702 in the same space as a fan, the component module 1700 may fit within standard dimensions without requiring additional length at the pump end of the module 1700. In an embodiment, the pump 1702 may circulate dielectric coolant within the component module 1700.

Further, the liquid tight end cap 1704 may be disposed adjacent to the pump 1702. The liquid tight end cap 1704 may include an O-ring seal or similar sealing mechanism configured to prevent leakage of dielectric coolant from the component module 1700. The liquid tight end cap 1704 may seal the component module 1700 at the pump end, maintaining the integrity of the dielectric coolant volume within the component module 1700. The liquid tight cap and the heat exchanger assembly 1712 may be disposed at opposing ends of the component module 1700, defining an internal volume therebetween.

The coolant hose 1706 may extend from the pump 1702 along a length of the component module 1700 toward the heat exchanger assembly 1712. The coolant hose 1706 may be configured to transfer coolant from the pump 1702 to the heat exchanger assembly 1712.

In some implementations, the coolant hose 1706 may be formed from a resilient material allowing the coolant hose 1706 to fit between one or more electrical components within the component module 1700. The ability of the coolant hose 1706 to be arranged between the one or more electrical components may allow the component module 1700 to maintain a size similar to that of traditional air-cooled component module 1600. In some aspects, the coolant hose 1706 may follow a path similar to a power cable route in traditional air-cooled component modules 1600, avoiding adding height to the component module 1700.

In one or more embodiments, the heat exchanger assembly 1712 may be disposed at an end of the component module 1700 opposite that of the pump 1702. The heat exchanger assembly 1712 may be constructed from copper or another thermally conductive material (e.g., aluminum). The heat exchanger assembly 1712 may include electrical component-side heat fins 1708 and power connection-side heat fins 1710 disposed on opposing sides of a thermal barrier.

The electrical component-side heat fins 1708 may be configured to interface with the dielectric coolant circulating within the component module 1700. The electrical component-side heat fins 1708 may receive heat from coolant that has absorbed heat from the one or more electrical components within the component module 1700. In some implementations, the electrical component-side heat fins 1708 may be skived heat fins or equivalent structures configured to transfer heat from the dielectric coolant to the heat exchanger assembly 1712.

The power connection-side heat fins 1710 may be configured to interface with external coolant supplied by an external liquid cooling system. The power connection-side heat fins 1710 may transfer heat from the heat exchanger assembly 1712 to the external coolant, such as facility water. In some implementations, the power connection-side heat fins 1710 may be skived heat fins or equivalent structures configured to transfer heat to the external coolant. The heat exchanger assembly 1712 may serve as a thermal barrier between the coolant within the component module 1700 and the external coolant, maintaining separation between the two cooling circuits while facilitating heat transfer.

Referring to FIG. 18, a dielectric coolant flow 1802 path through the component module 1700 is shown. In an embodiment, coolant within the component module 1700 may interface with and absorb heat from the one or more electrical components through direct contact. The warmed dielectric coolant may travel from the pump 1702 through the coolant hose 1706 to the heat exchanger assembly 1712, where the electrical component-side heat fins 1708 may receive heat from the warmed coolant. The heat absorbed by the component-side heat fins 1708 may be transferred to the connection-side heat fins 1710 via the thermal barrier. The heat exchanger assembly 1712 may transfer the heat from the power connection-side heat fins 1710 to the external coolant. The cooled dielectric coolant may then be recirculated back through the component module 1700 to continue the cooling cycle.

Moreover, the component module 1700 may include a sealed PCB passthrough at a rear wall of the component module 1700. A printed circuit board may pass through the rear wall of the component module 1700 to provide power and communication connections. The PCB passthrough may be sealed to prevent leakage of the dielectric coolant contained within the component module 1700. The sealed PCB passthrough may allow the component module 1700 to interface with a backplane or rack system while maintaining the integrity of the liquid-tight housing.

In some implementations, the internal volume of the component module 1700 may be nearly fully flooded with coolant. The internal volume may include an air gap to accommodate thermal expansion of the coolant during operation.

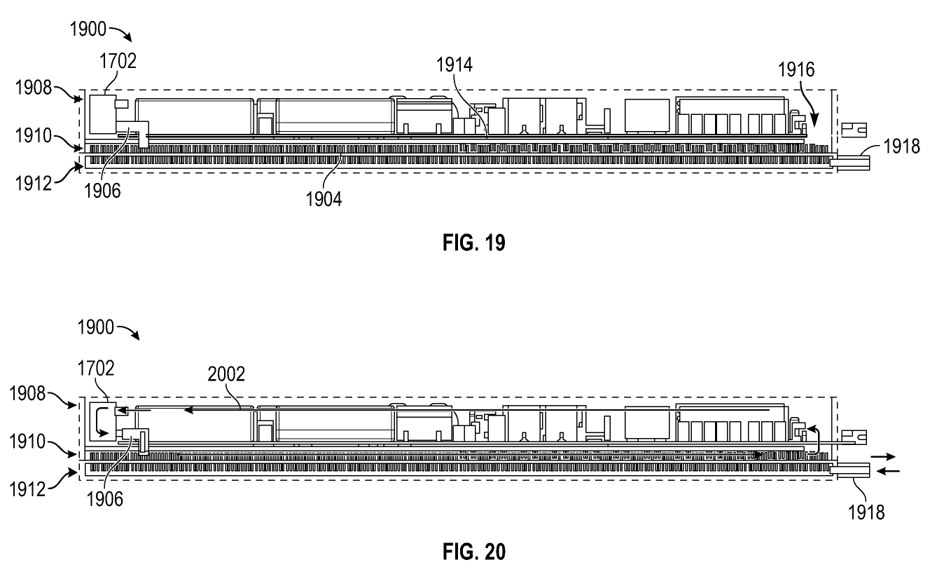

Moving to FIGS. 19-20, a three compartment component module 1900 is shown. The three compartment component module 1900 may incorporate the features and disclosures described with respect to component modules 102 and 1700.

The three compartment component module 1900 may provide an alternative configuration for liquid cooling within the modular liquid-cooled power distribution system. In the three compartment component module 1900, an elongated heat exchanger assembly 1904 may be disposed beneath a pump 1702, creating three distinct compartments within the three compartment component module 1900.

The three compartment component module 1900 may be divided into a first compartment 1908, a second compartment 1910, and a third compartment 1912. The first compartment 1908 may be disposed above the second compartment 1910, and the second compartment 1910 may be disposed above the third compartment 1912. The vertical arrangement of the first compartment 1908, the second compartment 1910, and the third compartment 1912 may provide separation between the dielectric coolant circulating within the three compartment component module 1900 and the external facility coolant supplied by an external liquid cooling system.

In an embodiment, the first compartment 1908 may be defined by a volume between a top wall of the three compartment component module 1900 and a barrier 1914. In particular, the first compartment 1908 may be defined by a top surface of the barrier 1914 and a bottom surface of the top wall of the three compartment component module 1900.

In an embodiment, the first compartment 1908 may house one or more electrical components. In some implementations, a PCB may be disposed within the first compartment 1908, with the one or more electrical components mounted on the PCB. The PCB may interface with the barrier 1914, or a gap may be positioned between a bottom surface of the PCB and the top surface of the barrier 1914.

The second compartment 1910 may be defined by a volume between the elongated heat exchanger assembly 1904 and the barrier 1914. In an embodiment, the elongated heat exchanger assembly 1904 may be disposed beneath the barrier 1914, such that the second compartment 1910 may be defined by a top surface of the elongated heat exchanger assembly 1904 and a bottom surface of the barrier 1914. The second compartment 1910 may house a first plurality of heat fins. The first plurality of heat fins may interface with and extend from the bottom surface of the barrier 1914 and/or the top surface of the elongated heat exchanger assembly 1904, increasing surface area for heat transfer between coolant and the elongated heat exchanger assembly 1904.

Furthermore, the barrier 1914 may include an opening 1916, wherein the first compartment 1908 and the second compartment 1910 are in fluid communication. The opening 1916 may be disposed at an end of the three compartment component module 1900 opposite that of the pump 1702. The opening 1916 may allow coolant to flow between the first compartment 1908 and the second compartment 1910.

The third compartment 1912 may be defined by a volume between a bottom surface of the top wall of the elongated heat exchanger assembly 1904 and a top surface of the bottom wall of the elongated heat exchanger assembly 1904. Alternatively, the third compartment 1912 may be defined by a volume between a bottom surface of the top wall of the elongated heat exchanger assembly 1904 and a bottom wall of the three compartment component module 1900. The third compartment 1912 may house a second plurality of heat fins.

In one or more embodiments, the second plurality of heat fins may interface with and extend from the top surface of the bottom wall of the elongated heat exchanger assembly 1904 or the bottom surface of the elongated heat exchanger assembly 1904, increasing surface area for heat transfer between facility coolant and the elongated heat exchanger assembly 1904. The elongated heat exchanger assembly 1904 may serve as a thermal barrier between the coolant in the second compartment 1910 and the facility coolant in the third compartment 1912, maintaining separation between the two cooling circuits while facilitating heat transfer.

A facility coolant supply 1918 may be positioned at an end of the three compartment component module 1900 opposite that of the pump 1702. In an embodiment, the facility coolant supply 1918 may provide connection points for external facility coolant to enter and exit the third compartment 1912. In some implementations, the third compartment 1912 may incorporate one or more quick disconnect fittings for connecting the third compartment 1912 to the external liquid cooling system. The quick disconnect fittings may allow external coolant to enter and leave the third compartment 1912.

Referring to FIG. 20, a dielectric coolant flow path 2002 through the three compartment component module 1900 is shown. To illustrate, dielectric coolant may submerge the one or more electrical components housed within the first compartment 1908, wherein it absorbs heat from the one or more electrical components through direct thermal contact.

Moreover, the pump 1702 may be disposed at one end of the three compartment component module 1900, and may circulate dielectric coolant therein. An outflow hose 1906 may extend from the pump 1702 and may transfer warmed dielectric coolant from the first compartment 1908 to the second compartment 1910. The outflow hose 1906 may traverse the barrier, allowing warmed dielectric coolant to be pumped from the first compartment 1908 into the second compartment 1910.

Upon entering the second compartment 1910, the warmed dielectric coolant may interface with the first plurality of heat fins facilitating thermal transfer between the warmed dielectric coolant and the elongated heat exchanger assembly 1904. For example, heat may transfer from the warmed dielectric coolant to the first plurality of heat fins to the elongated heat exchanger assembly 1904 (described in more detail below).

After heat has been removed from the dielectric coolant, the cooled dielectric coolant may be recirculated into the first compartment 1908. The cooled dielectric coolant may travel through the opening 1916 in the barrier, and re-enter the first compartment 1908. As warmed dielectric coolant is continuously pumped into the second compartment 1910, the cooled dielectric coolant may be forced from the second compartment 1910, through the opening 1916, into the first compartment 1908.

In some implementations, the cooled dielectric coolant may traverse the PCB prior to re-entering the first compartment 1908. The PCB may incorporate one or more apertures facilitating fluid communication between the first compartment 1908 and the second compartment 1910. The apertures may allow cooled dielectric coolant from the second compartment 1910 to enter the first compartment 1908. In some aspects, the apertures may be placed directly above the opening in the barrier. In other aspects, the apertures may be dispersed throughout the PCB to distribute dielectric coolant evenly across the first compartment 1908.

The spacing and sizing of the apertures may be customized to achieve specific flow rates and flow patterns. The customization of the apertures may allow for targeted cooling, directing a higher volume of cooled dielectric coolant to areas of the first compartment 1908 where components generating higher amounts of heat are located.

In one or more embodiments, facility coolant from the external liquid cooling system may enter the third compartment 1912 via the facility coolant supply 1918 and the one or more quick disconnect fittings. The facility coolant may interface with both the second plurality of heat fins housed within the third compartment 1912 and the elongated heat exchanger assembly 1904. The elongated heat exchanger assembly 1904 may serve as a barrier between the facility coolant and the dielectric coolant.

To illustrate, the facility coolant may remove heat from the elongated heat exchanger assembly 1904. As described above, warmed dielectric coolant may enter the second compartment 1910 and interface with the first plurality of heat fins. The heat absorbed by the first plurality of heat fins may transfer to the second plurality of heat fins through the top wall of the elongated heat exchanger assembly 1904. Upon entering the third compartment 1912, the facility coolant may interface with the second plurality of heat fins ultimately absorbing the heat from the second plurality of heat fins and exiting the third compartment 1912 to the external facility coolant system via the one or more quick disconnect fittings and the facility coolant supply 1918.

In some embodiments, a modular liquid-cooled power distribution system may comprise a component rack, one or more component modules mounted within the component rack, and an external liquid cooling system integrated with the component rack and configured to supply external coolant to the one or more component modules. Each component module may comprise a housing defining an internal volume containing dielectric coolant, one or more electrical components at least partially submerged in the dielectric coolant, and a heat exchanger configured to transfer heat from the dielectric coolant to the external coolant.

In some embodiments, each of the one or more component modules may comprise a first compartment and a second compartment, wherein the second compartment contains the one or more electrical components, and the heat exchanger is disposed within the first compartment.

In some embodiments, the first compartment may be configured to act as a sump having a lower coolant level than the second compartment, and the dielectric coolant may overflow from the second compartment into the first compartment via one or more apertures.

In some embodiments, each component module may further comprise a manifold positioned along a length of the second compartment, the manifold including a plurality of apertures configured to disperse cooled dielectric coolant across the one or more electrical components.

In some embodiments, each component module may further comprise a third compartment, wherein the external coolant from the external liquid cooling system interfaces with the heat exchanger in the third compartment to remove heat from the heat exchanger.

In some embodiments, each component module may comprise blind mate fittings configured to facilitate hot-swapping of the component modules without disrupting operation of the external liquid cooling system.

In some embodiments, each of the one or more component modules may further comprise a pump to circulate the dielectric coolant within the housing.

In some embodiments, each of the one or more component modules may further comprise a coolant hose disposed between the pump and the heat exchanger, the coolant hose configured to transfer the dielectric coolant from the pump to the heat exchanger.

In some embodiments, the component rack may include a power input configured to receive three-phase AC input and coolant inputs configured to supply the external coolant to each of the one or more component modules.

In one or more embodiments, a component module for a liquid-cooled power distribution system may comprise a housing defining an internal volume, dielectric coolant contained within the internal volume, one or more electrical components disposed within the internal volume and at least partially submerged in the dielectric coolant, a pump configured to circulate the dielectric coolant within the internal volume, and a heat exchange assembly configured to transfer heat from the dielectric coolant to an external coolant supplied by an external liquid cooling system.

In some embodiments, the housing may be configured to maintain a form factor compatible with air-cooled component modules.

In some embodiments, the component module may further comprise a coolant hose disposed between the pump and the heat exchange assembly, the coolant hose configured to transfer the dielectric coolant from the pump to the heat exchange assembly, wherein the coolant hose is formed from a resilient material configured to fit between the one or more electrical components within the housing.

In some embodiments, the heat exchange assembly may comprise a plurality of heat fins configured to receive heat from the dielectric coolant.

In some embodiments, the plurality of heat fins may comprise electrical component-side heat fins configured to interface with the dielectric coolant and power connection-side heat fins configured to interface with the external coolant.

In some embodiments, the housing may include a first compartment, a second compartment, and a third compartment, wherein the pump is disposed within the first compartment.

In some embodiments, the component module may further comprise blind mate fittings configured to connect the component module to power and coolant systems of a component rack upon insertion of the component module into the component rack.

Finally, other implementations of the disclosure will be apparent to those skilled in the art from consideration of the specification and practice of the disclosure disclosed herein. It is intended that the specification and examples be considered as exemplary only, with a true scope and spirit of the disclosure being indicated by the following claims.

Various elements, which are described herein in the context of one or more embodiments, may be provided separately or in any suitable subcombination. Further, the processes described herein are not limited to the specific embodiments described. For example, the processes described herein are not limited to the specific processing order described herein and, rather, process blocks may be re-ordered, combined, removed, or performed in parallel or in serial, as necessary, to achieve the results set forth herein.

It will be further understood that various changes in the details, materials, and arrangements of the parts that have been described and illustrated herein may be made by those skilled in the art without departing from the scope of the following claims.

All references, patents and patent applications and publications that are cited or referred to in this application are incorporated in their entirety herein by reference. Finally, other implementations of the disclosure will be apparent to those skilled in the art from consideration of the specification and practice of the disclosure disclosed herein. It is intended that the specification and examples be considered as exemplary only, with a true scope and spirit of the disclosure being indicated by the following claims.

What is claimed is:

1. A modular liquid-cooled power distribution system, comprising:
a component rack;
one or more component modules mounted within the component rack;
an external liquid cooling system integrated with the component rack and configured to supply external coolant to the one or more component modules; and
each component module comprising:
a housing defining an internal volume containing dielectric coolant;
one or more electrical components at least partially submerged in the dielectric coolant; and
a heat exchanger configured to transfer heat from the dielectric coolant to the external coolant.

2. The modular liquid-cooled power distribution system of claim 1, wherein each of the one or more component modules comprise:
a first compartment; and
a second compartment;
wherein the second compartment contains the one or more electrical components, and the heat exchanger is disposed within the first compartment.

3. The modular liquid-cooled power distribution system of claim 2, wherein the first compartment is configured to act as a sump having a lower coolant level than the second compartment, and wherein the dielectric coolant overflows from the second compartment into the first compartment via one or more apertures.

4. The modular liquid-cooled power distribution system of claim 2, wherein each component module further comprises a manifold positioned along a length of the second compartment, the manifold including a plurality of apertures configured to disperse cooled dielectric coolant across the one or more electrical components.

5. The modular liquid-cooled power distribution system of claim 2, wherein each component module further comprises a third compartment, wherein the external coolant from the external liquid cooling system interfaces with the heat exchanger in the third compartment to remove heat from the heat exchanger.

6. The modular liquid-cooled power distribution system of claim 1, wherein each component module comprises blind mate fittings configured to facilitate hot-swapping of the component modules without disrupting operation of the external liquid cooling system.

7. The modular liquid-cooled power distribution system of claim 1, wherein each of the one or more component modules further comprises:
a pump to circulate the dielectric coolant within the housing.

8. The modular liquid-cooled power distribution system of claim 7, wherein each of the one or more component modules further comprises:
a coolant hose disposed between the pump and the heat exchanger, the coolant hose configured to transfer the dielectric coolant from the pump to the heat exchanger.

9. The modular liquid-cooled power distribution system of claim 1, wherein the component rack includes a power input configured to receive three-phase AC input and coolant inputs configured to supply the external coolant to each of the one or more component modules.

10. A component module for a liquid-cooled power distribution system, comprising:
a housing defining an internal volume;
dielectric coolant contained within the internal volume;
one or more electrical components disposed within the internal volume and at least partially submerged in the dielectric coolant;
a pump configured to circulate the dielectric coolant within the internal volume; and
a heat exchange assembly configured to transfer heat from the dielectric coolant to an external coolant supplied by an external liquid cooling system.

11. The component module of claim 10, wherein the housing is configured to maintain a form factor compatible with air-cooled component modules.

12. The component module of claim 10, further comprising a coolant hose disposed between the pump and the heat exchange assembly, the coolant hose configured to transfer the dielectric coolant from the pump to the heat exchange assembly, wherein the coolant hose is formed from a resilient material configured to fit between the one or more electrical components within the housing.

13. The component module of claim 10, wherein the heat exchange assembly comprises a plurality of heat fins configured to receive heat from the dielectric coolant.

14. The component module of claim 13, wherein the plurality of heat fins comprises electrical component-side heat fins configured to interface with the dielectric coolant and power connection-side heat fins configured to interface with the external coolant.

15. The component module of claim 11, wherein the housing includes a first compartment, a second compartment, and a third compartment, wherein the pump is disposed within the first compartment.

16. The component module of claim 11, further comprising blind mate fittings configured to connect the component module to power and coolant systems of a component rack upon insertion of the component module into the component rack.
